(19) United States
(12) Patent Application Publication
(10) Pub. No.: US 2024/0290792 A1
(43) Pub. Date: Aug. 29, 2024

(54) ARRAY SUBSTRATES, DISPLAY PANELS, AND METHOD FOR MANUFACTURING ARRAY SUBSTRATES

(71) Applicant: Guangzhou China Star Optoelectronics Semiconductor Display Technology Co., LTd., Guangzhou (CN)

(72) Inventors: Wei LIU, Guangzhou (CN); Yanhong MENG, Guangzhou (CN)

(73) Assignee: Guangzhou China Star Optoelectronics Semiconductor Display Technology Co., LTd., Guangzhou (CN)

(21) Appl. No.: 18/343,653

(22) Filed: Jun. 28, 2023

Related U.S. Application Data
(63) Continuation of application No. PCT/CN2023/085505, filed on Mar. 31, 2023.

(30) Foreign Application Priority Data
Feb. 23, 2023 (CN) 202310168253.9

(51) Int. Cl. H01L 27/12; G02F 1/1368

(52) U.S. Cl. CPC H01L 27/1218; G02F 1/1368; H01L 27/1262

(57) ABSTRACT

Disclosed are an array substrate, a display panel, and a method for manufacturing an array substrate, wherein the array substrate includes a base substrate and a protection layer, the protection layer is disposed on the base substrate and covers the base substrate, and a first through-hole for discharging moisture is formed in the protection layer. The present disclosure improves the stability of the thin film transistor in the array substrate by providing the through-hole in the protection layer to discharge moisture without additional structures, and improves the phenomenon of negative bias leakage of the display panel without changing the spatial arrangement.

### CROSS-REFERENCE TO RELATED APPLICATIONS

This application is a continuation of International Application No. PCT/CN2023/085505, filed on Mar. 31, 2023, which claims priority to Chinese Patent Application No. 202310168253.9, filed on Feb. 23, 2023. The disclosures of the aforementioned applications are incorporated herein by reference in their entireties.

### TECHNICAL FIELD

The present disclosure relates to the display technology, and in particular, to an array substrate, a display panel, and a method for manufacturing an array substrate.

### BACKGROUND

During 8 Mask process for manufacturing display panels containing an oxide, a large amount of moisture will be generated. The oxide is sensitive to moisture, and therefore the electrical property of the device may be influenced by moisture, resulting in a series of problems that, for example, the thin film transistor (TFT) may be turned on at a negative pressure to cause current leakage of pixels of the display panel, electrostatic discharge (ESD) or the like may lead to failure of the TFT, and the display panel cannot discharge static electricity.

### SUMMARY

The present disclosure aims to provide an array substrate, a display panel and a method for manufacturing an array substrate, so as to solve a problem in the art, such as negative bias leakage of a display panel caused by moisture generated in a process of manufacturing a display panel.

According to a first aspect, the present disclosure provides an array substrate including:
a base substrate, which includes a thin film transistor layer having a channel region; and
a protection layer disposed on the base substrate and covering the base substrate, the protection layer having a first through-hole for discharging moisture, and the first through-hole being disposed close to the channel region.

According to a second aspect, the present disclosure provides a display panel including an array substrate including:
a base substrate, which includes a thin film transistor layer having a channel region; and
a protection layer disposed on the base substrate and covering the base substrate, the protection layer having a first through-hole for discharging moisture, and the first through-hole being disposed close to the channel region.

According to a third aspect, the present disclosure provides a method of manufacturing an array substrate, the method including:
preparing a base substrate, which includes a thin film transistor layer having a channel region;
preparing a protection layer on the base substrate, the protection layer covering the base substrate; and
preparing a first through-hole in the protection layer at a position corresponding to the channel region.

### BRIEF DESCRIPTION OF THE DRAWINGS

In order to illustrate the embodiments of the present disclosure, the accompanying drawings used in the description of the embodiments will be briefly described below. It will be apparent that the described accompanying drawings are merely some of the embodiments of the present disclosure, and other drawings may be obtained by those skilled in the art without involving any inventive effort on the basis of these drawings.

FIG. 1 is a schematic diagram of a structure of an array substrate according to an embodiment of the present disclosure.

FIG. 2 is a schematic diagram of another structure of an array substrate according to an embodiment of the present disclosure.

FIG. 3 is a schematic diagram of another structure of an array substrate according to an embodiment of the present disclosure.

FIG. 4 is a schematic diagram of another structure of an array substrate according to an embodiment of the present disclosure.

### DETAILED DESCRIPTION

Embodiments of the present disclosure will be clearly and fully described below in conjunction with drawings of the present disclosure. It is apparent that the described embodiments are only a part of embodiments of the present disclosure, rather than all the embodiments. Based on the embodiments in the present disclosure, all other embodiments obtained by those skilled in the art without creative effort fall within the scope of the present disclosure.

In the description of the present disclosure, it should be understood that terms indicating orientations or position relationships, such as “center”, “longitudinal”, “lateral”, “length”, “width”, “thickness”, “upper”, “lower”, “front”, “rear”, “left”, “right”, “vertical”, “horizontal”, “top”, “bottom”, “inside”, or “outside”, are based on orientations or position relationships illustrated in the drawings. The terms are used to facilitate and simplify the description of the present disclosure, rather than indicate or imply that the devices or elements referred to herein are required to have specific orientations or be constructed or operate in the specific orientations. Accordingly, the terms should not be construed as limiting the present disclosure. In addition, the term “first”, “second” are for illustrative purposes only and are not to be construed as indicating or imposing a relative importance or implicitly indicating the number of technical features indicated. Thus, a feature that limited by “first” or “second” may expressly or implicitly include one or more features. In the description of the present disclosure, the meaning of “plural” is two or more, unless otherwise specifically defined.

In the present disclosure, a phrase “exemplary” refers to “as an example”, “illustrative”, or “explanative”. Any embodiment described as an “exemplary” embodiment in the present disclosure is not necessarily construed as being more preferable or advantageous than other embodiments. In order to enable any person skilled in the art to implement and use the present disclosure, the following description is provided. In the following description, the details are listed for the purpose of explanation. It should be understood that those of ordinary skill in the art can realize that the present disclosure can also be implemented without using these specific details. In other instances, well-known structures and processes will not be elaborated to avoid unnecessary details to obscure the description of the present disclosure. Therefore, the present disclosure is not intended to be limited to the illustrated embodiments, but is consistent with the widest scope that conforms to the principles and features disclosed in the present disclosure.

Embodiments of the present disclosure provide an array substrate, a display panel, and a method for manufacturing an array substrate, which are described in detail below.

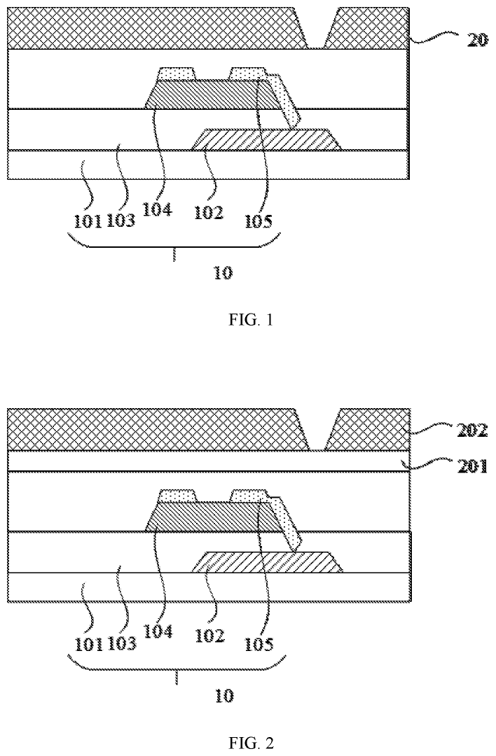

Referring to FIG. 1, it is a schematic diagram of a structure of an array substrate according to an embodiment of the present disclosure. In the embodiment shown in FIG. 1, the array substrate includes: a base substrate 10, which includes a thin film transistor layer having a channel region; a protection layer 20, which is disposed on the base substrate 10 and covers the base substrate 10. A first through-hole is formed in the protection layer 20 for discharging moisture generated in the preparation of the array substrate. The first through-hole is formed at a position close to the channel region to discharge moisture in the channel region of the thin film transistor, so as to protect the thin film transistor. The process of discharging moisture will be described in the following embodiments.

The array substrate according to the embodiment of the present disclosure includes the base substrate and the protection layer, the protection layer is disposed on the base substrate and covers the base substrate, and the first through-hole for discharging moisture is formed in the protection layer. By providing the through-hole in the protection layer to discharge moisture, the present disclosure improves the stability of the thin film transistor of the array substrate without additional structure, and improves a phenomenon of negative bias leakage of the display panel without changing the spatial arrangement.

The structure of the array substrate according to the present disclosure is suitable to an array substrate having a fringe field switching (FFS) structure and containing an oxide. Such array substrates include a layer composed of a polymer film. A large amount of moisture will be generated in the process of preparing the polymer film. A channel in the array substrate is sensitive to hydrogen ions of the moisture, and excess hydrogen ions may cause carriers in the channel to increase, so that the thin film transistor TFT is negatively biased. Pixel cells may be turned on at a low voltage, resulting in current leakage thereof, and in turn abnormality-displaying of the display panel. Therefore, in the present disclosure, the through-hole is provided to discharge moisture, thereby reducing the amount of hydrogen ions.

In FIG. 1, the protection layer 20 on the base substrate 10 may be a single polymer film. The first through-hole may be formed only in the polymer film. When the through-hole is formed in the protection layer (i.e., the polymer film), moisture can directly escape from the through-hole, and thus is discharged. Generally, a part of moisture may be discharged by a via hole which does not penetrate through the protection layer. However, in order to improve the efficiency of discharging moisture, a through-hole, which penetrates through the protection layer, is generally provided. Specifically, compared with the via hole, the through-hole is closer to the thin film transistor TFT, which is readily influenced, of the array substrate in a vertical direction, and moisture is more easily discharged from the through-hole. In addition, the area for moisture emitting of the through-hole is larger, which is advantageous for discharging the moisture.

For the array substrate shown in FIG. 1, although moisture remains during the preparation of the polymer film, the moisture in the polymer film can be discharged from the array substrate by the through-hole of the polymer film in a subsequent baking process, thereby preventing hydrogen ions of the moisture from entering the channel of the array substrate.

In an embodiment of the present disclosure, a material of the polymer film includes, but is not limited to, soluble polyfluoroalkoxy (PFA) having good chemical corrosion resistance and high temperature resistance. The protection layer may be a transparent protection layer.

In another embodiment of the present disclosure, the protection layer may be a multilayer structure. Referring to FIG. 2, it is a schematic diagram of another structure of an array substrate according to an embodiment of the present disclosure. In the schematic diagram of the array substrate shown in FIG. 2, the protection layer 20 may include a polymer film 201 and a first passivation layer 202. The first passivation layer 202 is disposed on the polymer film and covers the polymer film 201. A first through-hole is formed in the first passivation layer 202 to discharge moisture.

Similar to the array substrate shown in FIG. 1, the through-hole is formed in a film layer above the base substrate to discharge moisture, except that the protection layer 20 in FIG. 2 includes the polymer film 201 and the first passivation layer 202, and the protection layer in FIG. 1 includes only the polymer film. In this case, the through-hole is formed in the first passivation layer 202, similarly removing residual moisture in the preparation of the polymer film. The first passivation layer 202 may protect the array substrate, while removing excess moisture.

For the array substrate shown in FIG. 2, although the protection layer 20 includes the polymer film and the first passivation layer 202, the through-hole is formed only on the first passivation layer 202. In the process of preparing the array substrate shown in FIG. 2, an air extraction process may be performed during the preparation of the polymer film, and at this time, a part of moisture can be volatilized. Subsequently, an electrode layer is prepared. A baking process may be performed during the preparation of the electrode layer, and moisture in the polymer film layer may also be volatilized by the through-hole formed in the first passivation layer 202.

Certainly, it is to be noted that the prepared electrode layer includes a common electrode layer and a pixel electrode layer, and it is necessary to keep away from the through-hole in the protection layer when preparing the electrode layer. A material of the electrode layer includes, but is not limited to, one or more of indium tin oxide, indium zinc oxide, aluminum tin oxide, aluminum zinc oxide, and indium germanium zinc oxide.

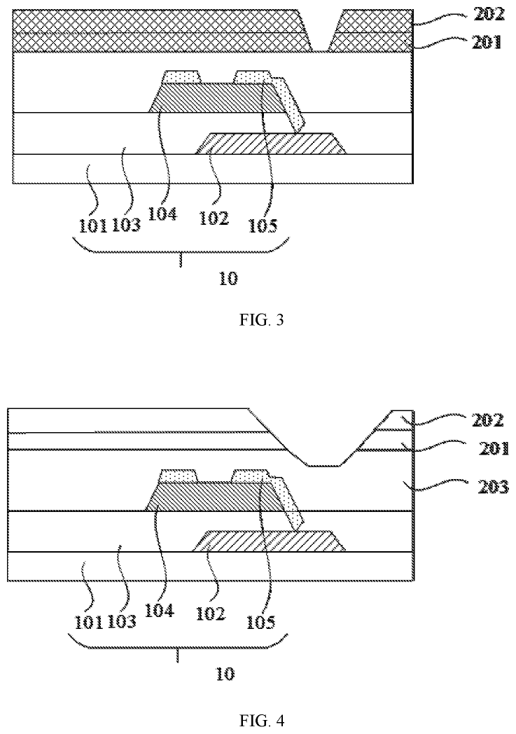

Referring to FIG. 3, it is a schematic diagram of another structure of an array substrate according to an embodiment of the present disclosure. In FIG. 3, the protection layer 20 includes a polymer film 201 and a first passivation layer 202. However, unlike the embodiment shown in FIG. 2, a second through-hole is formed in the polymer film, and a third through-hole is formed in the first passivation layer 202, in the array substrate shown in FIG. 3. That is, in the embodiment shown in FIG. 3, the polymer film 201 and the first passivation layer 202 have a through-hole, respectively, and the second through-hole in the polymer film 201 is in communication with the third through-hole in the first passivation layer 202. As shown in FIG. 3, the position of the second through-hole in the polymer film 201 is the same as that of the third through-hole in the first passivation layer 202, so that the second through-hole is in communication with the third through-hole. In this case, the first through-hole substantively includes the second through-hole formed in the polymer film and the third through-hole formed in the first passivation layer.

Compared with the array substrate shown in FIG. 2, the array substrate shown in FIG. 3 further provides the second through-hole in the polymer film 201 at a position corresponding to the third through-hole, on the basis of forming the third through-hole in the first passivation layer 202. By providing the through-holes in both the film structures, and positioning the two through-holes correspondingly to form a complete through-hole penetrating through the protection layer, the area for discharging moisture of the through-hole is greatly increased, thereby improving the efficiency of moisture volatilization.

Referring to FIG. 4, it is a schematic diagram of another structure of an array substrate according to the present disclosure. In the embodiment shown in FIG. 4, the protection layer is also a multilayer structure. The protection layer may include a second passivation layer 203, a polymer film 201, and a first passivation layer 202 which are stacked. The second passivation layer 203 is disposed on the base substrate to protect the base substrate. For the embodiment shown in FIG. 4, the first through-hole may include a first via hole formed in the second passivation layer 203, a second through-hole formed in the polymer film, and a third through-hole formed in the first passivation layer. The first via hole, the second through-hole and the third through-hole are communicated with each other to obtain a complete moisture escaping pathway.

The second passivation layer is a structure closest to the thin film transistor layer in the protection layer, the via hole is therefore formed on the second passivation layer in order to protect the thin film transistor layer while realizing a moisture emission function. However, in order to protect the thin film transistor layer, the via hole formed on the second passivation layer generally cannot extend through the second passivation layer. That is, the second passivation layer has a via hole, rather than a through hole.

For the array substrate shown in FIG. 4, this arrangement can further increase the area of the through-hole, i.e., the area for moisture emission, compared with the array substrate in the other embodiments, thereby improving the efficiency of moisture emission.

In the embodiments shown in FIGS. 1 to 4, the base substrate in the array substrate may include the following structures:
a glass substrate 101;
a gate metal layer 102 on the glass substrate 101;
a gate insulating layer 103 on the gate metal layer 102, the gate insulating layer 103 covering the gate metal layer 102;
a metal oxide layer 104 on the gate insulating layer 103, the metal oxide layer 104 being positioned correspondingly to the position of the gate metal layer 102;
a source-drain layer 105 on the metal oxide layer 104, the source-drain layer 105 including a source and a drain that are independent of each other.

In the above embodiments of the array substrate, the first through-hole generally needs to be disposed close to the thin film transistor of the array substrate, or rather close to the channel region of the thin film transistor layer of the array substrate. This is because the channel in the array substrate is sensitive to hydrogen ions of moisture. Therefore, it is necessary to prevent hydrogen ions of the moisture from entering the channel as much as possible. By arranging the through-hole close to the channel, the moisture in the vicinity of the channel can be discharged as much as possible, thereby avoiding influence on the TFT.

The above embodiments illustrate that the number of the first through-hole is one. In other embodiments, the first through-hole in the protection layer may include a plurality of first sub-through-holes, and the positions of the plurality of first sub-through-holes may be set according to actual requirements. For example, the plurality of first sub-through-holes may be arranged around the channel region of the thin film transistor layer or, depending on the actual moisture situation, at a region where the moisture is concentrated.

In the above embodiments, the number and position of the first through-hole may be set according to actual requirements. The first through-hole is generally a through-hole that penetrates through the protection layer in a vertical direction (without damaging the thin film transistor), and has a size set according to the actual size of the array substrate in a horizontal direction. In an embodiment, a width in the horizontal direction and a height in the vertical direction of the first through-hole are greater than or equal to 7 μm.

In the embodiments of the present disclosure, a cross-sectional shape of the first through-hole formed in the protection layer 20 in the vertical direction may be a trapezoidal structure having a greater upper edge and a less lower edge, so that the area for moisture emitting can be further increased compared with a rectangular structure, thereby improving the efficiency of moisture emission. The cross-section of the first through-hole may be a circular or a rectangular shape, or the like.

It is to be noted that for the array substrate of the present disclosure, in addition to the above structures, the array substrate further includes other film layers. The moisture is generally completely discharged during the preparation of the array substrate. As a result, with regard to the finished complete array substrate, the through-hole in the protection layer do not communicate with the outside, thereby preventing external moisture from entering the inside of the array substrate again through the through-hole. Exemplarily, the first through-hole may be filled with a water absorbing material, which not only ensures flatness of the upper surface of the array substrate, but also prevents external moisture from entering the array substrate.

An embodiment of the present disclosure further provides a display panel including the array substrate according to any one of the above embodiments. The display panel may further include a counter substrate and a liquid crystal layer. The counter substrate is disposed opposite to and spaced from the array substrate. The liquid crystal layer is disposed between the counter substrate and the array substrate. The display panel may be a color filter on array (COA) panel, or a non-COA panel.

The present disclosure further provides a method for manufacturing an array substrate, which includes:
preparing a base substrate, which includes a thin film transistor layer including a channel region; preparing a protection layer on the base substrate, the protection layer covering the base substrate; forming a first through-hole in the protection layer at a position corresponding to the channel region.

In some embodiments, the protection layer may be a multilayer stack structure. A height of the first through-hole in the vertical direction may vary depending on the number of film layers of the protection layer. The method for manufacturing the array substrate according to the present disclosure can generate the array substrate according to any one of the above embodiments. In the present disclosure, the specific methods for preparing the different film layers of the array substrate and the first through-hole can refer to the prior art, which are not limited herein.

In the above embodiments, the description of each embodiment has its own emphasis, and the parts of an embodiment that are not described in detail can be found in the detailed description of other embodiments above, which will not be repeated herein.

In specific implementation, each of the above units or structures may be implemented as a separate entity, or may be implemented in any combination as the same entity or several entities. The specific implementation of each of the above units or structures can be found in the method embodiments above and will not be repeated herein.

The specific implementation of each of the above operations can be found in the embodiments above and will not be repeated here.

The array substrate, the display panel and the method for preparing the array substrate according to the embodiments of the present disclosure are illustrated in detail. Exemplary embodiments are applied herein to illustrate the principles and embodiments of the present disclosure. The description of the above embodiments is merely provided to help understand the method of the present disclosure and the core idea thereof. Variations may be made to those skilled in the art in both the specific implementation and the application scope in accordance with the teachings of the present disclosure. In summary, the contents of the specification should not be construed as limiting the present disclosure.

What is claimed is:

1. An array substrate comprising:
a base substrate, which comprises a thin film transistor layer having a channel region; and
a protection layer disposed on the base substrate and covering the base substrate, the protection layer having a first through-hole for discharging moisture, and the first through-hole being disposed close to the channel region.

2. The array substrate according to claim 1, wherein the protection layer is a single polymer film, and the first through-hole is formed in the polymer film to discharge moisture.

3. The array substrate according to claim 1, wherein the protection layer comprises a polymer film and a first passivation layer on the polymer film, and the first passivation layer covers the polymer film; and
the first through-hole is formed in the first passivation layer to discharge moisture.

4. The array substrate according to claim 1, wherein the protection layer comprises a polymer film and a first passivation layer on the polymer film, and the first passivation layer covers the polymer film; and
the first through-hole comprises a second through-hole formed in the polymer film, and a third through-hole formed in the first passivation layer, and the second through-hole is in communication with the third through-hole.

5. The array substrate according to claim 1, wherein the protection layer comprises a second passivation layer, a polymer film, and a first passivation layer which are stacked in sequence, and the second passivation layer is disposed on the base substrate.

6. The array substrate according to claim 5, wherein the first through-hole comprises a first via hole formed in the second passivation layer, a second through-hole formed in the polymer film, and a third through-hole formed in the first passivation layer, and the first via hole, the second through-hole, and the third through-hole are in communication with each other.

7. The array substrate according to claim 1, wherein the first through-hole is filled with a water-absorbing material.

8. The array substrate according to claim 1, wherein the first through-hole comprises a plurality of first sub-through-holes disposed around the channel region.

9. The array substrate according to claim 1, wherein a cross-sectional shape of the first through-hole in a vertical direction is a trapezoidal structure having a greater upper edge and a less lower edge.

10. The array substrate according to claim 1, wherein a width of the first through-hole in a horizontal direction and a height of the first through-hole in a vertical direction are greater than or equal to 7 microns.

11. A display panel comprising an array substrate, wherein the array substrate comprises:
a base substrate, which comprises a thin film transistor layer having a channel region; and
a protection layer disposed on the base substrate and covering the base substrate, the protection layer having a first through-hole for discharging moisture, and the first through-hole being disposed close to the channel region.

12. The display panel according to claim 11, wherein the protection layer is a single polymer film, and the first through-hole is formed in the polymer film to discharge moisture.

13. The display panel according to claim 11, wherein the protection layer comprises a polymer film and a first passivation layer on the polymer film, and the first passivation layer covers the polymer film; and
the first through-hole is formed in the first passivation layer to discharge moisture.

14. The display panel according to claim 11, wherein the protection layer comprises a polymer film and a first passivation layer on the polymer film, and the first passivation layer covers the polymer film; and
the first through-hole comprises a second through-hole formed in the polymer film, and a third through-hole formed in the first passivation layer, and the second through-hole is in communication with the third through-hole.

15. The display panel according to claim 11, wherein the protection layer comprises a second passivation layer, a polymer film, and a first passivation layer which are stacked in sequence, and the second passivation layer is disposed on the base substrate.

16. The display panel according to claim 15, wherein the first through-hole comprises a first via hole formed in the second passivation layer, a second through-hole formed in the polymer film, and a third through-hole formed in the first passivation layer, and the first via hole, the second through-hole, and the third through-hole are in communication with each other.

17. The display panel according to claim 11, wherein the first through-hole is filled with a water absorbing material.

18. The display panel according to claim 11, wherein the first through-hole comprises a plurality of first sub-through-holes disposed around the channel region.

19. The display panel according to claim 11, further comprising an counter substrate and a liquid crystal layer, wherein the counter substrate is disposed opposite to and spaced from the array substrate, and the liquid crystal layer is disposed between the counter substrate and the array substrate.

20. A method of manufacturing an array substrate, comprising:
preparing a base substrate, which comprises a thin film transistor layer having a channel region;
preparing a protection layer on the base substrate, the protection layer covering the base substrate; and
preparing a first through-hole in the protection layer at a position corresponding to the channel region.
